(19) United States
(12) Patent Application Publication
(10) Pub. No.: US 2005/0166953 A1
(43) Pub. Date: Aug. 4, 2005

(54) Solar energy concentrator

(76) Inventor: John D. Baldeschwieler, Pasadena, CA (US)

Correspondence Address: COUDERT BROTHERS LLP, 333 SOUTH HOPE STREET, 23RD FLOOR, LOS ANGELES, CA, 90071, US

(21) Appl. No.: 10/992,872

(22) Filed: Nov. 18, 2004

Related U.S. Application Data
(60) Provisional application No. 60/523,874, filed on Nov. 20, 2003.

(51) Int. Cl. H01L 25/00; H02N 6/00

(52) U.S. Cl. 136/246; 136/247

(57) ABSTRACT

The present invention comprises a method and apparatus for concentrating light. The invention comprises a panel with a top and bottom surface area relatively larger than the surface area of the edges of the panel. Solar cells are disposed on the edge surfaces. When light shines on the panel, it is transmitted into the interior of the panel material and redirected to impinge on the solar cells at the edge areas. In one embodiment this is accomplished by causing the interior of the panel to fluoresce, where the fluoresced light is directed to the solar cells, resulting in the direct generation of electricity. In another embodiment, the invention is used to aid in a photocatalytic process by concentrating light on integrated channels through which a catalytic material is flowing. The light energy is used to create hydrogen and oxygen which may be used in fuel cells.

### CROSS-REFERENCE TO RELATED APPLICATION(S)

The present application claims the benefit of priority from pending U.S. Provisional Patent Application No. 60/523,874, entitled “Solar Energy Concentrator,” filed on Nov. 20, 2003, which is herein incorporated by reference in its entirety.

### BACKGROUND OF THE INVENTION

1. Field of the Invention

The present invention relates to the field of solar concentration devices.

Portions of the disclosure of this patent document contain material that is subject to copyright protection. The copyright owner has no objection to the facsimile reproduction by anyone of the patent document or the patent disclosure as it appears in the Patent and Trademark Office file or records, but otherwise reserves all rights whatsoever.

2. Background Art

Because of the increasing costs and volatile availability of energy produced by fossil fuels, solar energy has become an important alternative resource for generating energy. In order to make the use of solar energy practical, it must be affordable and competitive with other forms of energy.

One solar energy technology employs photovoltaic cells. Photovoltaic cells are constructed of various semiconducting materials and directly convert sunlight into electricity. Typically, photovoltaic cells are made from Silicon (Si). However, other more expensive materials may be used to increase the cell's efficiency in converting light to electricity. These materials include Gallium Phosphide (GaP), Indium Phosphide (InP), Gallium Arsenide (GaAs), and Indium Arsenide (InAs).

A photovoltaic cell contains two different types of semiconducting layers, a positively charged (p-type) layer and a negatively charged (n-type) layer. A voltage is generated in a photovoltaic cell when radiant energy falls on the boundary of a photovoltaic cell's two dissimilar semiconductor materials. Since the cost of the photovoltaic cells themselves typically is a large part of the total cost of harnessing solar energy, an effective way to reduce the cost of solar energy production is to concentrate sunlight on the photovoltaic cells so that fewer cells or a smaller area of cells are needed to produce the same amount of energy. Currently many solar energy designs incorporate mirrors or some other sort of focusing optics in order to concentrate solar energy. However, these designs have a number of disadvantages.

One disadvantage of current focusing systems is that in order for these systems to maximize their efficiency in solar energy concentration, the focusing system needs to track the sun. This is because the position of the sun itself is what is focused on by the photovoltaic cells. The tracking of the sun requires that the system have some sort of motor and tracking system that moves the focusing system in line with the sun's movement. The requirement of a motor is expensive and has the additional problems of requiring care and maintenance. Additionally, the tracking of the sun will require that the tracking system be able to account for the inclination of the earth and change of sun's position as the earth rotates. A tracking system that is able to account for these characteristics is complex and expensive.

Another problem with the focusing system is that, along with focusing the desired visible or ultraviolet light, it focuses infrared or heat. Since heat is being focused, it is being intensified, and as a result the housing of the solar cells becomes hot and needs to be cooled. Some sort of cooling device, such as a liquid cooling system, is required to cool the housing. Similar to the motor, the cooling device has the drawbacks of being expensive as well as requiring care and maintenance.

An additional disadvantage with the focusing system is that the system will only work efficiently on a sunny day. This is because on a cloudy day there is no point image to focus on the concentrating sun. Thus, there is a need for an alternative system that concentrates solar energy.

### SUMMARY OF THE INVENTION

The present invention comprises a method and apparatus for concentrating light. The invention comprises a panel with a top and bottom surface area relatively larger than the surface area of the edges of the panel. Solar cells are disposed on the edge surfaces. When light shines on the panel, it is transmitted into the interior of the panel material and redirected to impinge on the solar cells at the edge areas. In one embodiment this is accomplished by causing the interior of the panel to fluoresce, where the fluoresced light is directed to the solar cells, resulting in the direct generation of electricity. The fluoresced light may be a result of materials embedded in the panel that fluoresce in response to sunlight. In other instances, the panel is constructed of a material that has the desired fluorescing properties. The invention may also be implemented as stacked panels where each panel filters a specific wavelength band of light. In another embodiment, the invention is used to aid in a photocatalytic process by concentrating light on integrated channels through which a catalytic material is flowing. The light energy is used to create hydrogen and oxygen which may be used in other energy producing endeavors, such as fuel cells.

### BRIEF DESCRIPTION OF THE DRAWINGS

These and other features, aspects and advantages of the present invention will become better understood with regard to the following description, appended claims, and accompanying drawings where:

FIG. 1 illustrates the structure of a panel with photovoltaic cells.

FIG. 2A illustrates the cross section of a panel with photovoltaic cells and depicts fluoresce occurring within the panel.

FIG. 2B illustrates the cross section of a panel with photovoltaic cells and depicts light being reflected off the surface.

FIG. 3 is an illustration of the structure of a multi-layer device with photovoltaic cells and depicts fluoresce occurring within in each layer, according to one embodiment of the present invention.

FIG. 4A illustrates the structure of a photocatalytic panel with a manifold attached to it.

FIG. 4B shows an exploded view of a photocatalytic panel, according to one embodiment of the present invention.

FIG. 5 is an illustration of the chemical reaction of photocatalysis of water using titanium dioxide as the catalytic material, according to an embodiment of the present invention.

FIG. 6 depicts a hollow fiber module used for gas separation, according to one embodiment of the present invention.

FIG. 7 illustrates the structure of a hybrid panel, according to another embodiment of the present invention.

### DETAILED DESCRIPTION OF THE INVENTION

The embodiments of the present invention are directed to a method and an apparatus for concentrating solar energy and for facilitating photocatalyic reactions. In the following description, numerous details are set forth in order to provide a more thorough description of the present invention. It will be apparent, however, to one skilled in the art, that the present invention may be practiced without these specific details. In other instances, well known features have not been described in detail so as not to unnecessarily obscure the present invention.

The present invention consists of a relatively thin transmissive panel that allows sunlight to pass through. The panel includes, or is comprised of a material which fluoresces when light is radiated on it. This fluorescing light is internally reflected toward the edges of the panel and is directed onto photovoltaic cells placed on the edge surfaces. A reflective treatment is also applied to the panel's surfaces. This treatment allows light to be reflected back inside the panel so that some of light can be internally reflected. The present invention minimizes the amount of escaping light and has the overall effect of concentrating solar energy inside the panel and directing it to the panel edges.

Panel with Photovoltaic Cells

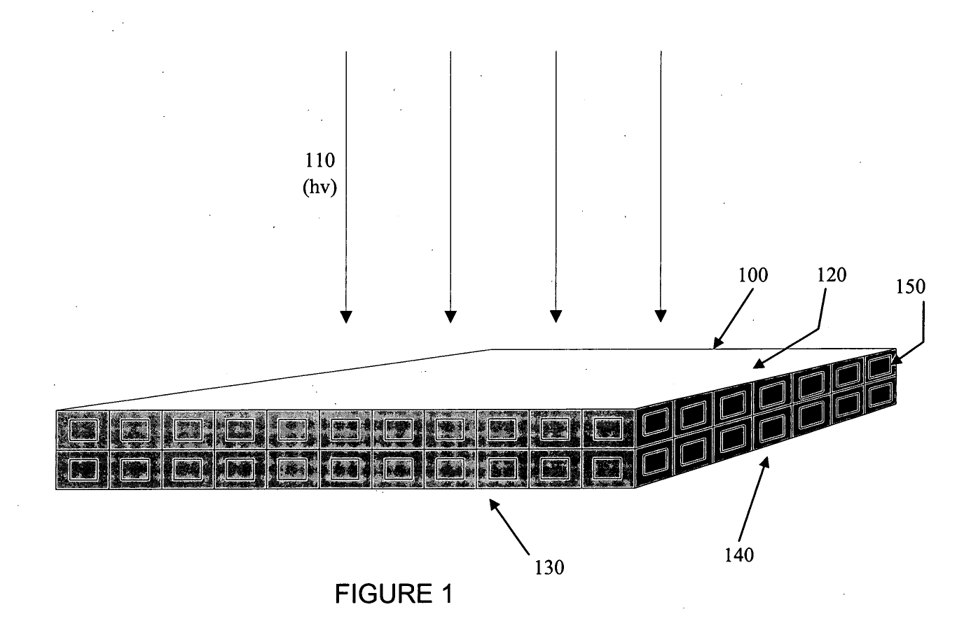

FIG. 1 illustrates the structure of a panel with photovoltaic cells in one embodiment of the invention. The panel 100 of FIG. 1 comprises a planar piece of transmissive material. The panel 100 is thin with a relatively large surface area 120 such that the surface areas 130 and 140 of the edges is small with respect to the surface area 120 of the top and bottom faces. The edges of the panel are lined with photovoltaic cells such as cell 150.

One function of the panel 100 with photovoltaic cells 150 is to concentrate light 110 onto the photovoltaic cells. There are various ways that the panel 100 is able to concentrate solar energy. One way is by creating a fluorescing effect. In order for the panel to fluoresce, the panel is either impregnated with a pigment or material that fluoresces, or the panel's material itself is chosen to have this inherent property.

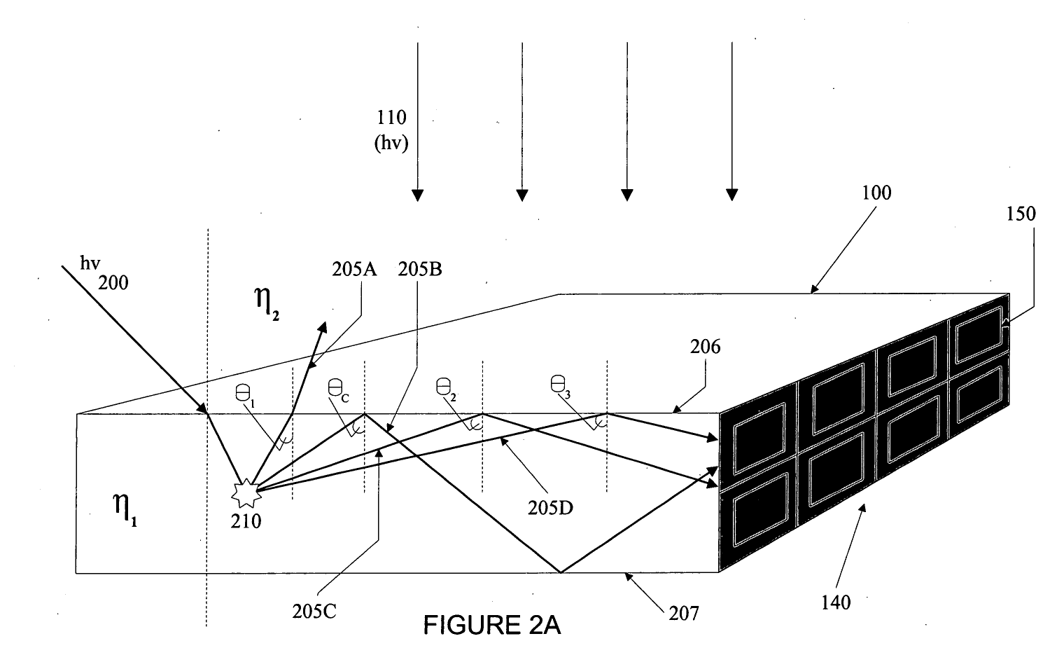

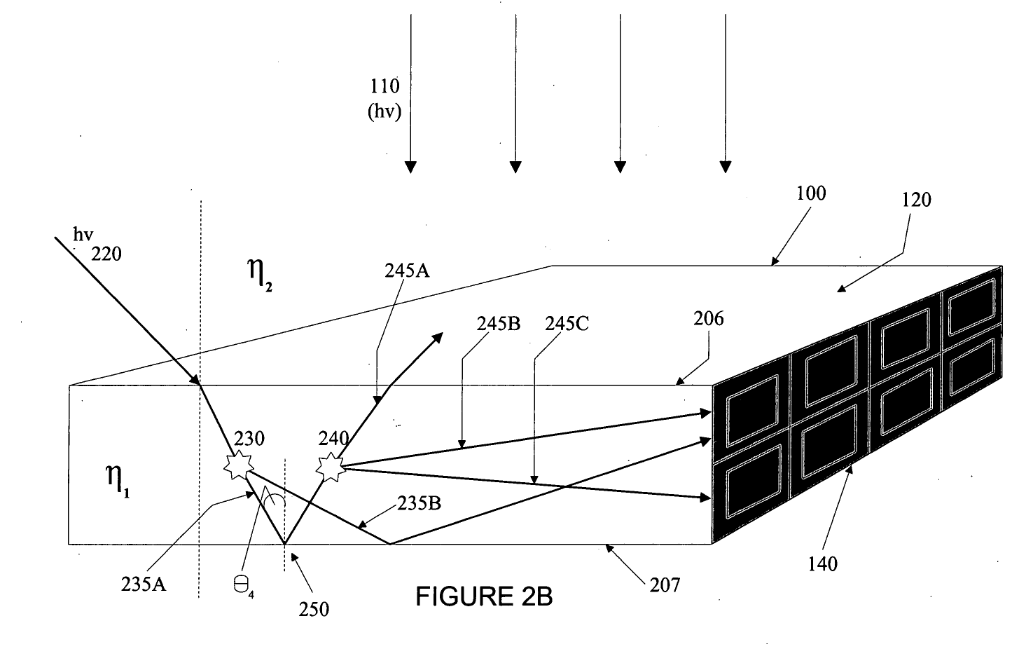

FIG. 2A is an illustration of the operation of the invention. A cross section of a panel 100 with photovoltaic cells is depicted in FIG. 2A. As sunlight 110 is shone upon the panel 100, it strikes particles 210 inside the panel, causing them to fluoresce. Element 210 in FIG. 2A represents a particle that is fluorescing. Fluorescence refers to the phenomenon of light being absorbed at one wavelength and nearly immediately thereafter being reradiated at a different wavelength. When fluorescing occurs, light is radiated and scattered from the fluorescing particle. This occurs because when a light photon hits an atom or molecule in the panel, one of the atom or molecule's electrons is excited to a higher energy level. When the electron falls back to its normal level, it releases energy in the form of another photon and heat. The wavelength (λ) of the emitted photon is determined by the atom or molecule's electronic and vibrational energy level structure.

An example light ray 200 in FIG. 2A enters the panel 100 and strikes particle 210 in the panel 100. Particle 210 is caused to fluoresce. When a particle 210 is fluoresced, multiple beams (205A-205D) of light are radiated and scattered at various directions within the panel 100. The angle at which each light beam is scattered determines whether the light beam will escape or will be internally reflected. This angle is referred to as the angle of incidence (θ_{Incid}). The angle of incidence is defined as the angle between the projection of the scattered light beam and the normal to the surface of the panel. The dashed lines in FIG. 2A each indicate the normal to the surface 206 of the panel at the point at which one of the plurality of fluoresced light beams 205A-205D strikes it. Light that is scattered at an angle of incidence that is less than or equal to the critical angle (θ_{c}) will escape out of the panel. For example, in FIG. 2A, the angle of incidence for the scattered light beam 205A is θ₁. In this depiction, θ₁, is less than θ_{c}. Since θ₁ is less than θ_{c}, light that is scattered at θ₁ escapes.

However, light that is scattered at an angle of incidence that is equal to or exceeds the critical angle will not produce a refracted ray, but rather will be internally reflected. In FIG. 2A, for example, the angles of incidence for scattered light beams 205B, 205C, and 205D are θ_{c}, θ₂ and θ₃, respectively. Since light beam 205B is scattered at θ_{c} it is internally reflected onto the photovoltaic cells that lie on edge 140. In this drawing, θ₃>θ₂>θ_{c}. Since both θ₃ and θ₃ are greater than θ_{c}, light that is scattered at either θ₂ or θ₃ is also internally reflected onto the photovoltaic cells that lie on edge 140.

The critical angle is calculated as a function of the index of refraction (η) of the first medium that the light ray travels in and the index of refraction of the second medium that the light ray travels in. For example, in FIG. 2A, the first medium that light ray 200 travels in is air and the second medium that light ray 200 travels in is the panel's primary material. In FIG. 2A, the index of refraction for air is denoted by 12 and the primary material's index of refraction is denoted by η₁. The index of refraction for air equals 1. Thus, for FIG. 2A, η₂ equals 1. The formula for calculating the critical angle is arcsin (η₂/η₁). For example, if the panel's primary material is chosen to have an index of refraction equal to 1.5 (i.e. η₁=1.5), the critical angle (θ_{c}) equals arcsin (1.0/1.5) which yields 41.8°.

Another embodiment enhances the ability of the panel to concentrate solar energy by making its surface reflective. This is achieved by coating the panel's surfaces with a reflective treatment. This reflective surface is able to reflect light that might ordinarily escape back into the panel 100. The reflective surface is able to accomplish this because it is either chosen to have a different index of refraction (η) than the panel's primary material, or it is fully reflective as with a mirror surface.

FIG. 2B is an illustration of how the panel reflects light. A cross section of a panel with photovoltaic cells is depicted in FIG. 2B. In FIG. 2B, surface 207 has a reflective treatment. As an example, light ray 220 enters the panel and a particle 230 in the panel is fluoresced. Element 230 in FIG. 2B represents a particle that is fluorescing. In FIG. 2B, the angle of incidence for a scattered light beam 235A is θ₄. In this depiction, θ₄ is less than θ_{c}. Since θ₄ is less than θ_{c}, light that is scattered at θ₄ would escape if there were no reflective surface. However, since the panel has a reflective treatment, rather than the light escaping, light beam 235A is reflected 250 off of surface 207.

After the light beam 235A is reflected 250, particle 240 in the panel is fluoresced, which causes multiple light beams to be radiated and scattered. Element 240 in FIG. 2B represents a particle that is fluorescing. In FIG. 2B, the angle of incidence for light beam 245A is less than the critical angle. Thus, since the angle of incidence for light beam 245A is less than the critical angle, light beam 245A escapes. Conversely, in FIG. 2B, light beams 245B and 245C are scattered from element 240 onto the photovoltaic cells that lie on edge 140.

It should be noted that a single light beam radiating into panel 100 may undergo a path of being reflected off of surface 207 multiple times. If this were to occur, the above stated process would simply repeat multiple times. For example, light beam 245A could have been reflected off of surface 207 instead of escaping. If this were to have occurred, light beam 245A would have been reflected back inside the panel and caused another particle in the panel to fluoresce. When this particle is fluoresced, multiple beams of light would radiate and scatter at various directions within the panel 100. The process of light beams being reflected off of the surface of panel 100 or internally reflected would simply repeat.

Another embodiment enhances the ability of the panel 100 to concentrate solar energy by making the outer surface of panel 100 anti-reflective. This is achieved by coating the panel's outer surface with an anti-reflective treatment. For example, in FIG. 2B, surface 206 of panel 100 could be coated with a ¼ wavelength anti-reflective coating to reduce losses by unwanted reflection of the incident sunlight.

According to another embodiment, the panel 100 is able to concentrate sunlight by the use of scattering centers. There is a provision of materials that scattering centers can be made from. In this embodiment, scattering centers are embedded inside the transmission medium of the panel 100. Scattering centers are sites where light is reflected and scattered. For example, when a light beam hits a scattering center inside the panel 100, multiple light beams are scattered. Some of these light beams will be internally reflected onto the photovoltaic cells that lie on the edges of the panel 100.

Multi-layer Device with Photovoltaic Cells

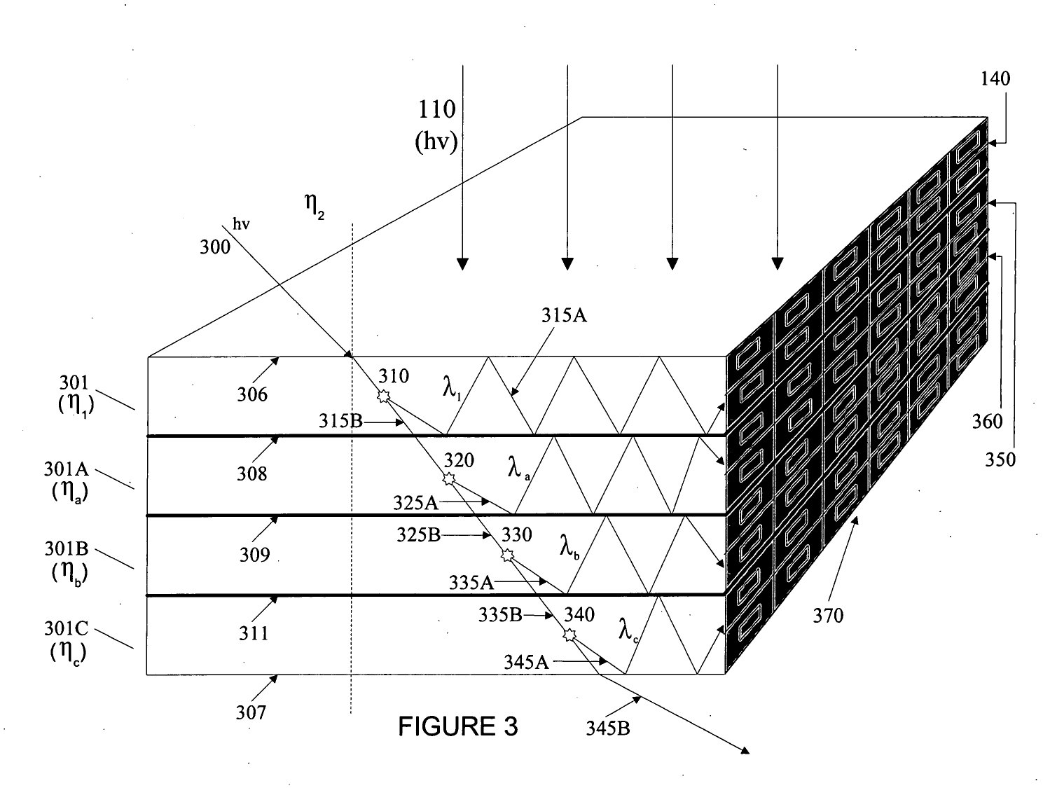

According to another embodiment of the present invention, multiple panels with photovoltaic cells may be stacked on top of one another such that they form a multi-layer device. FIG. 3 illustrates the structure of a multi-layer device. In this multi-layer device, the absorbing characteristic for each panel is chosen such that each panel internally reflects a different portion of the solar spectrum onto the photovoltaic cells. This enables the multi-layer device to internally reflect light at multiple specific wavelengths and/or wavebands and, thus, absorb a larger fraction of the total solar spectrum.

FIG. 3 is an illustration of how the multi-layer device internally reflects light at different wavelengths and/or wavebands. A cross section of a multi-layer device is depicted in FIG. 3. The multi-layer device in FIG. 3 is comprised of four panels with photovoltaic cells. These four panels in FIG. 3 are 301, 301A, 301B, 301C. As sunlight is emitted into each panel, particles inside each panel are fluoresced. Elements 310, 320, 330, and 340 in FIG. 3 each represent a particle that is being fluoresced. In order for sunlight to pass through to each successive panel, only the bottom surface 307 of the device will have a reflective treatment. Thus, the surfaces 308, 309, and 311 that lie in between the panels will not have a reflective treatment. Additionally, the top surface 306 could have an anti-reflective treatment, according to one embodiment.

As an example, in FIG. 3, light ray 300 enters the first panel 301 and a particle 310 is fluoresced. When element 310 is fluoresced, multiple beams of light are radiated and scattered within the first panel 301. A scattered light beam be will be internally reflected if its scattering angle is greater than or equal to the critical angle. In FIG. 3, light beam 315A is scattered at an angle greater than the critical angle and, thus, light beam 315A will be internally reflected onto the photovoltaic cells that lie on edge 140. Conversely, in FIG. 3, light beam 315B is scattered at an angle less than the critical angle and, thus, light beam 315B will escape from the first panel 301 into the second panel 301A.

The absorbing material for the first panel 301 is chosen such that the first panel will internally reflect light at a specific wavelength or waveband. The wavelength or waveband of the light beam 315A that is being internally reflected in the first layer 301 is denoted as λ₁. In FIG. 3, the device's first layer 301 contains absorbing material 1 that has an index of refraction equal to η₁. Also, in FIG. 3, the index of refraction for air is denoted as η₂, which is equal to 1. Thus, the critical angle for the first layer 301 equals arcsin (η₂/η₁), which equals arcsin (1/η₁).

In FIG. 3, light 315B that is not internally reflected in the first layer 301 will pass through to the second layer 301A. As light 315B enters the second layer 301A, a particle 320 is fluoresced. Multiple beams of light are radiated and scattered within the second panel 301A when element 320 is fluoresced. In FIG. 3, light beam 325A is scattered at an angle greater than the critical angle and, thus, light beam 325A will be internally reflected onto the photovoltaic cells that lie on edge 350. However, in FIG. 3, light beam 325B is scattered at an angle less than the critical angle and, thus, light beam 325B will escape from the second panel 301A into the third panel 301B.

The second panel's 301A absorbing material is chosen such that light at a specific wavelength or waveband will be internally reflected. The wavelength or waveband of the light beam 325A that is internally reflected in the second layer 301A is denoted as λₐ. In FIG. 3, the device's second layer 301A contains absorbing material that has an index of refraction equal to ηₐ. Thus, the critical angle for the second layer 301A equals arcsin (η₁/ηₐ.

Light that is not internally reflected in the second layer 301A will pass through to the third layer 301B. As light 325B enters the third layer 301B, a particle 330 is fluoresced. When element 330 is fluoresced, multiple beams of light are radiated and scattered within the third panel 301B. In FIG. 3, light beam 335A is scattered at an angle greater than the critical angle and, thus, light beam 335A will be internally reflected onto the photovoltaic cells that lie on edge 360. However, in FIG. 3, light beam 335B is scattered at an angle less than the critical angle and, thus, light beam 335B will escape from the second panel 301A into the third panel 301B.

The third panel's 301B absorbing material is chosen such that light at a specific wavelength or waveband will be internally reflected. The wavelength or waveband of the light beam 335A that is internally reflected in the third layer 301B is denoted as η_{b}. The device's third layer 301B contains absorbing material b that has an index of refraction equal to η_{b}. Thus, the critical angle for the third layer 301B equals arcsin (ηₐ/η_{b}).

In FIG. 3, light that is not internally reflected in the third layer 301B will pass to the fourth layer 301C. As light 335B enters the fourth layer 301C, a particle 340 is fluoresced. When element 340 is fluoresced, multiple beams of light are radiated and scattered within the fourth panel 301B. In FIG. 3, light beam 345A is scattered at an angle greater than the critical angle and, thus, light beam 345A will be internally reflected onto the photovoltaic cells that lie on edge 370. Conversely, in FIG. 3, light beam 335B is scattered at an angle less than the critical angle and, thus, light beam 335B will escape from the fourth panel 301C.

The fourth panel's 301C absorbing material is chosen such that light at a specific wavelength or waveband will be internally reflected. The wavelength or waveband of the light beam 345A that is internally reflected in the fourth layer 301C is denoted as λ_{b}. The device's fourth layer 301C contains absorbing material c that has an index of refraction equal to η_{c}. Thus, the critical angle for the fourth layer 301C equals arcsin (η_{b}/η_{c}).

Some of the light that is not internally reflected in the fourth layer 301C will not escape, but rather will be reflected back inside the fourth layer 301C. This is because the fourth layer 301C, being the last layer of the multi-layer device, has its bottom surface 207 coated with a reflective treatment. Once the light is reflected back, particles in the fourth layer will fluoresce and cause some of the light to be internally reflected onto the photovoltaic cells that lie on edge 370.

Photocatalytic Panel

According to another embodiment, the present invention provides for a transmissive panel to concentrate solar energy onto channels that are filled with a solution that facilitates photocatalysis. Photocatalysis is the acceleration of a photoreaction by the presence of a catalyst. Various photocatalytic reactions can be facilitated in the present invention. One such reaction is the photocatalysis of water (H₂O), which yields hydrogen (H₂) that can be used as an energy source.

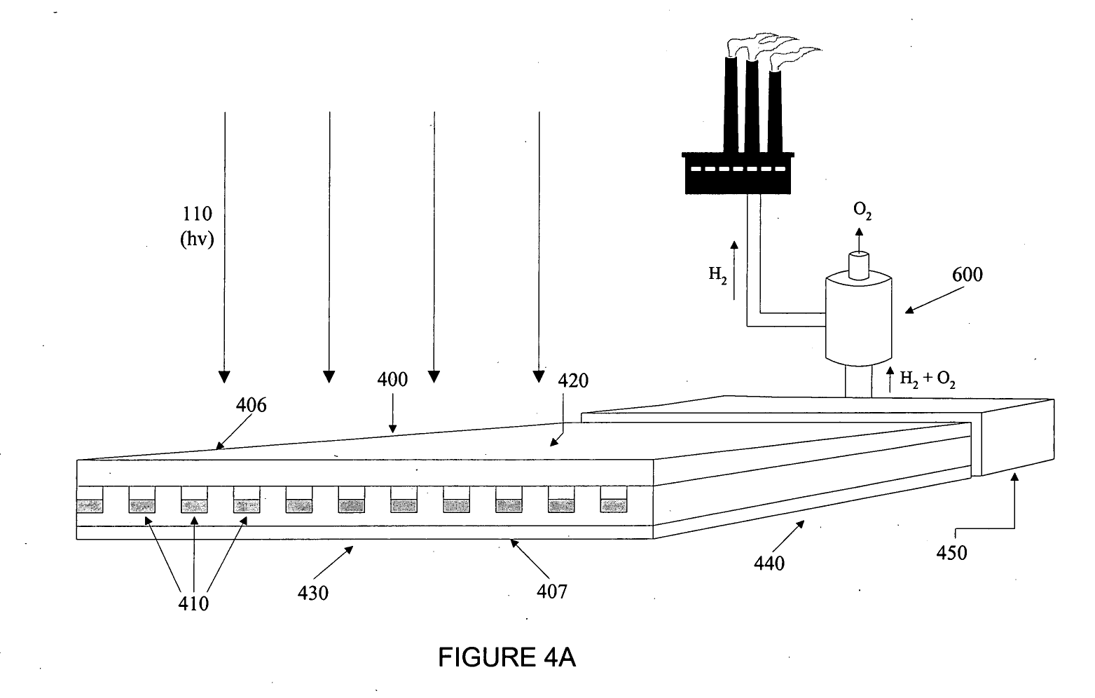

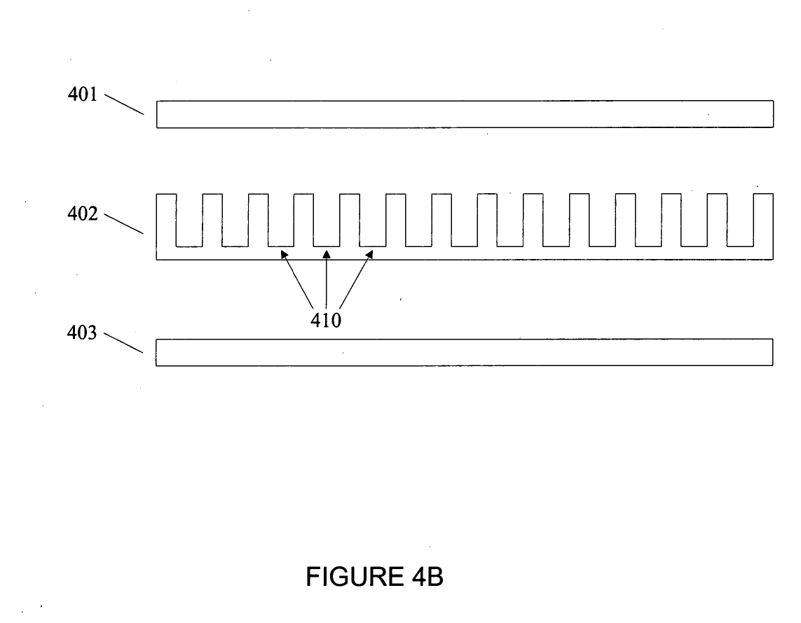

FIG. 4A illustrates the structure of a photocatalytic panel. The panel of FIG. 4A comprises a planar piece of transmissive material 400. The panel 400 is thin with a very large surface area 420 such that the area of the edges 430 and 440 is small with respect to the area 420 of the surface. The planar piece consists of three layers. These three layers are shown in an exploded diagram in FIG. 4B. The top 401 and bottom 403 layers serve as covers for the middle layer 402, and the middle layer 402 has a series of channels 410 formed into it. The channels 410, depicted in both FIGS. 4A and 4B, are filled with a solution that allows for photocatalytic reactions. Since the channels are formed from and surrounded by transmissive material, sunlight 110 is able to irradiate onto the solution, which is flowing in the channels 410. The channels 410 can be laid out in various arrangements. Examples of arrangements for the channels 410 include parallel and serpentine layouts. For example, the channels 410 depicted in FIGS. 4A and 4B are laid out in a parallel row format.

One function of the photocatalytic panel is to concentrate sunlight 110 onto the channels' 410 solution, which allows for photocatalytic reactions. There are different ways the panel 400 is able to concentrate solar energy. One way is by fluorescing. In order for the panel 400 to fluoresce, the panel 400 is either impregnated with a pigment that fluoresces, or the panel's material itself is chosen to have this inherent property. Another way is by reflecting some light off its reflective surface. This is achieved by coating the panel's surface 407 with a reflective treatment, which reflects some of the light that would normally escape back inside the panel. The reflective surface is able to reflect light back to the channels 410 because either the coating has a different index of refraction (η) than the panel's primary material, or the coating is fully reflective as with a mirror surface. Additionally, another way that the panel 400 is able to concentrate sunlight is to coat the top surface 406 with an anti-reflective treatment, according to one embodiment.

Another function of the photocatalytic panel is to facilitate photocatalytic reactions. A photocatalytic reaction uses a catalyst to accelerate a photoreaction. There are a provision of choices of photocatalytic reactions that can be employed by the present invention. One example is the photocatalysis of water (H₂O). This reaction uses sunlight to assist in the breakdown of water (H₂O) to yield hydrogen (H₂) and oxygen (O₂). In this reaction, titanium dioxide (TiO₂), also known as titania, is used as the photocatalyst. Titanium dioxide is commonly used as a photocatalyst for the decomposition of organic compounds. In this embodiment, the panel's channels 410 are filled with a solution of water (H₂O) and platinum (Pt) coated titanium dioxide (TiO₂) particles. A thin platinum film is deposited on the titanium dioxide particles via vapor deposition.

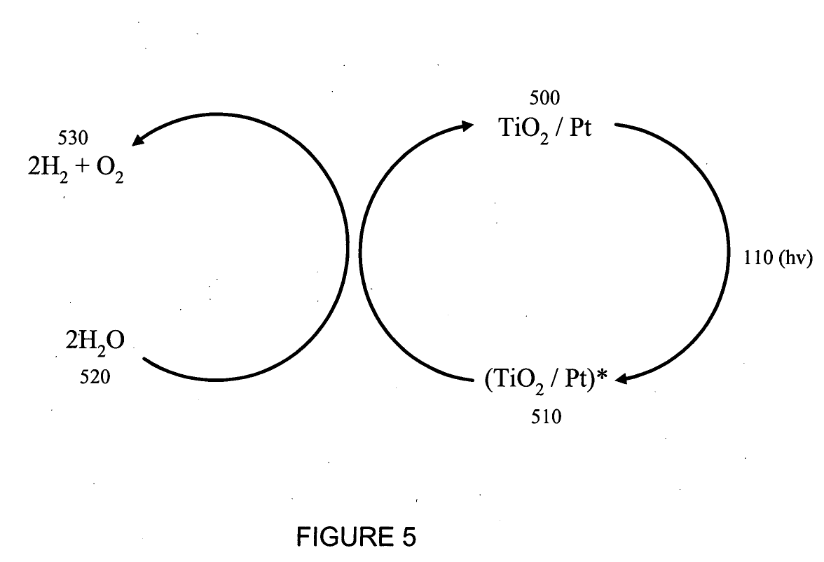

FIG. 5 illustrates the photocatalytic reaction of water (H₂O) 520 using platinum coated titanium dioxide (TiO₂/Pt) 500 as the photocatalyst. During this reaction, when sunlight 110 irradiates the titanium dioxide particles 500, the titanium dioxide particles 500 absorb the incident photons. This causes the titanium dioxide particles to be elevated to an excited state 510. In FIG. 5, the excited state of titanium dioxide 510 is denoted by an asterisk (*). When the titanium dioxide particles are in an excited state 510, this increases the ease of bond making and braking, which ultimately renders the organic reactant 520, water, to its desired products 530, hydrogen and oxygen. Titanium dioxide (TiO₂), being the catalytic entity here, participates in and accelerates the chemical transformation of water, while itself remaining unaltered at the end of each catalytic cycle. Thus, the titanium dioxide particles are re-circulated through the channels, and are able to be used for multiple successive reactions. Note that many other photocatalytic materials also might be possible.

Once the hydrogen and oxygen products are created, the resulting hydrogen gas may be used as an energy source. For example, the resulting hydrogen gas can be burned in an internal combustion engine or in a fuel cell to produce direct electricity. However, some sort of product extractor is needed to collect the hydrogen gas. Various types of product extractors can be used. One type of product extractor is a manifold. For this embodiment, in FIG. 4A, a manifold 450 is connected to the panel 400 and receives the resulting hydrogen and oxygen gases from the channels 410.

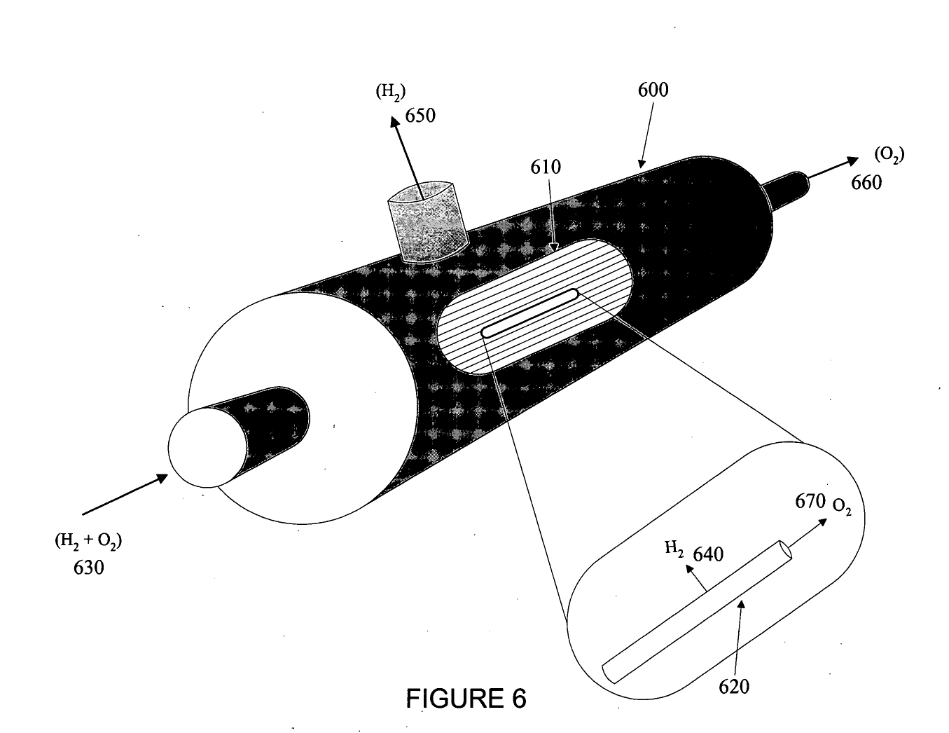

Once the gas products are received by the product extractor, some form of gas separator is needed to separate the hydrogen gas from the oxygen gas. One type of gas separator is hollow fiber separator. In this scheme, multiple individual hollow fibers are bundled together and packed in cylindrical modules. FIG. 6 illustrates a module 600 of hollow fibers 610. The wall of each individual hollow fiber 620 consists of two layers. One layer is a very thin, dense separation membrane layer. This thin layer provides, ideally, all of the mass transfer resistance and separation ability of the hollow fiber. The other layer is a porous polymer layer that provides mechanical support for the thin membrane layer, but offers little or no mass transfer resistance.

Gas separation occurs when gas is flowed under pressure into the module through the feed 630. After the gas is feed 630 into the module, it is distributed to the bores of the individual hollow fibers 620. Hydrogen gas permeates 640 through the wall of the fibers into the shell of the hollow-fiber module 600. Hydrogen is more permeable than oxygen because it has a lower molecular weight. The hydrogen gas permeating through the fibers and into the shell is collected and leaves the module as a permeate stream 650.

Because hydrogen is more permeable than oxygen, the gas in the fiber 620 bore is enriched with oxygen as it moves through the fiber lumens from the feed 630 to the residue end of the module 660. Thus, when the gas leaves the module as a residue 660 stream, the gas consists mainly of oxygen gas 670.

Another photocatalytic reaction that can be employed by the present invention is artificial photosynthesis. Artificial photosynthesis converts carbon dioxide from the air to sugar and other carbon products. This process can be used to reduce the large amounts of carbon dioxide that is emitted into the atmosphere from power stations, cars, etc. Additionally, this process has the potential to produce a range of useful byproducts including fuel and food. The overall chemical reaction for photosynthesis is: 12H₂O+6CO₂+light→C₆H₁₂O₆(glucose)+6O₂+6H₂O.

In real photosynthesis, nature uses chlorophyll as the catalyst for the reaction. Chlorophyll operates as a catalyst because it absorbs light and acts as an electron-transfer agent. However, for artificial photosynthesis an alternative catalyst needs to be used because chlorophyll decomposes quickly in an artificial system. Numerous alternative catalysts can be used. Examples of catalysts include catalysts made from robust transition metal complexes.

Hybrid Panel

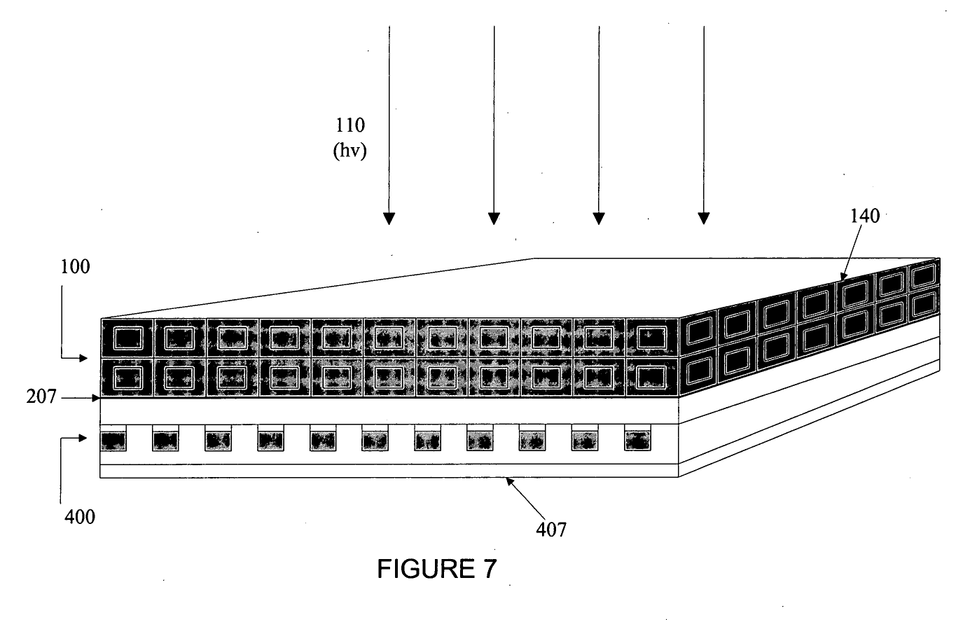

According to another embodiment of the present invention, a panel with photovoltaic cells may be stacked on top of a photocatalytic panel such that they form a hybrid panel device. FIG. 7 illustrates the structure of a hybrid panel device. In this hybrid panel device, sunlight 110 radiates into the panel with photovoltaic cells 100. Light that is not internally reflected onto the photovoltaic cells that lie on edge 140 will pass through to the photocatalytic panel 400. In order for sunlight to pass through to the photocatalytic panel, only the bottom surface 407 of the hybrid panel device will have a reflective treatment. Thus, the surface 207 that lies in between the panels will not have a reflective treatment.

Thus, a solar concentrating panel has been described in conjunction with one or more specific embodiments. The invention is defined by the following claims and their full scope of equivalents.

1. A solar concentrator comprising:
a panel having an upper surface area that is larger than a side surface area,
the panel comprising a material that fluoresces when struck by light and directs fluoresced light toward the side surface area.

2. The concentrator of claim 1 further including photovoltaic cells disposed on a side surface.

3. The concentrator of claim 2 further including anti-reflective coating on an upper surface of the panel.

4. The concentrator of claim 3 further including the interior side of the upper surface being reflective.

5. The concentrator of claim 1 wherein the material that fluoresces is an impurity introduced to the panel.

6. The concentrator of claim 2 further including multiple layers with each layer comprising a material that fluoresces at a different wavelength.

7. A photocatalytic panel comprising:
a panel having an upper surface area that is larger than a side surface area,
the panel comprising a material that fluoresces when struck by light,
the panel having formed therein at least one channel that receives a catalytic material.

8. The panel of claim 7 wherein the catalytic material produces hydrogen and oxygen when exposed to the fluoresced light.

9. The panel of claim 8 wherein the catalytic material is water and titania.

10. The panel of claim 8 further including photovoltaic cells disposed on a side surface.
